(19) United States
(12) Patent Application Publication
(10) Pub. No.: US 2013/0032860 A1
(43) Pub. Date: Feb. 7, 2013

(54) HFET with low access resistance

(71) Applicants: Fabio Alessio Marino, San Jose, CA (US); Paolo Menegoli, San Jose, CA (US)

(72) Inventors: Fabio Alessio Marino, San Jose, CA (US); Paolo Menegoli, San Jose, CA (US)

(21) Appl. No.: 13/136,333

(22) Filed: Aug. 1, 2011

(51) Int. Cl. H01L 29/778; H01L 21/335

(52) U.S. Cl. 257/194; 438/285; 257/E29.246; 257/E21.403

(57) ABSTRACT

A novel semiconductor power transistor is presented. The semiconductor structure is simple and is based on a Hetero-structure FET structure, where the access regions have been eliminated so as to effectively obtain a lower specific on-resistance, and a higher control on the transport properties of the device, drastically reducing the dispersion phenomena associated with these regions. The present invention can be realized both with polar and non-polar (or semi-polar) materials, without requiring delta doping implantation. It can be fabricated as an enhancement or depletion mode device with much higher control on the device threshold voltage with respect to state-of-the-art HFET devices, and achieving superior RF switching performance. Furthermore, due to the absence of access regions, enhancement mode devices can be realized without discontinuity in the channel conductivity, which results in an even lower on-resistance.

### BACKGROUND OF THE INVENTION

1. Field of the Invention

The present invention is in the field of semiconductor structures. The present invention is further in the field of semiconductor structures of transistor devices. The present invention further relates to the field of integrated devices and circuits. The implementation is not limited to a specific technology, and applies to either the invention as an individual component or to inclusion of the present invention within larger systems which may be combined into larger integrated circuits.

2. Brief Description of Related Art

The semiconductor transistor is the most important component for large integrated circuits. In the last three decades, field effect transistors (FETs) used in current integrated circuit process technologies have undergone a continuous shrinking of the semiconductor area needed for elementary components, and new materials including III-V and II-VI semiconductor compounds have been introduced to improve the device performance. However the need to further improve on its general performance while reducing its cost is still a necessity that poses a significant challenge.

In particular, the demand for high bit rate communication, millimeter wave applications and high frequency power conversion requires the development of devices with high cut-off frequencies and low specific R_{DSon} (measured in Ω*mm²). The silicon area is directly proportional to the cost of the integrated circuit and a low on-resistance is always desirable to increase the efficiency of the circuit and to reduce the power dissipation and therefore the temperature of the chip. Furthermore, a lower specific on-resistance allows the fabrication of devices with smaller gate capacitance and therefore better RF performance.

One of the main candidates for these applications is the High Electron Mobility Transistors (HEMTs), which generally uses III-V compounds semiconductor materials, such as InAs (indium arsenide), GaAs (gallium arsenide), AlAs (aluminum arsenide) and their alloys (InGaAs and InAlAs) on InP substrate, or III-V Nitride materials such as AlN (aluminum nitride), GaN (gallium nitride), InN (indium nitride) and their alloys (AlGaN, InGaN and InAlN). At the present time, very high cut-off frequencies f_{T} have been obtained with these devices.

An example of High electron mobility transistor (HEMT), also known as hetero-structure FET (HFET), is reported in Fujita et al. (U.S. Pat. No. 5,319,223) and Takikawa et al. (U.S. Pat. No. 4,958,203). This device is a field effect transistor incorporating a junction between two materials with different bandgaps (i.e., a heterojunction) used as channel instead of a doped region as in MOSFET devices. HEMTs avoid impurity scattering through the use of high mobility electrons generated using the heterojunction of a highly-doped wide-bandgap n-type donor-supply layer (e.g. AlGaAs) and a non-doped narrow-bandgap channel layer with no dopant impurities (e.g. GaAs). The electrons generated in the thin n-type wide-bandgap layer drop completely into the narrow-bandgap layer where they are free to move without being affected by impurity scattering. This method to create an electron channel is called modulation doping.

The use of InAs, InAlAs, GaAs and InGaAs materials rather than Si (Silicon) provides two significant advantages. First of all, the room temperature mobility is more than 5 times larger, while the saturation velocity is about twice that of silicon. Second, it is possible to fabricate semi-insulating (SI) GaAs substrates which eliminate the problem of absorbing microwave power in the substrate due to free carrier absorption.

Nitride semiconductors are wide gap semiconductors. For example, GaN (gallium nitride) and AlN (aluminum nitride) exhibit band gaps of 3.4 eV and 6.2 eV, respectively, at ambient temperature. An advantage of nitride semiconductors is that they have a larger insulation breakdown electric field and a greater electron saturation drift speed than semiconductors such as GaAs or Si. The properties of large band gap materials (such as GaN) make them ideally suited to operation at elevated temperatures, because they become intrinsic at much higher temperature than narrow band gap materials, and sustain high current or voltage levels, since they exhibit a high breakdown field.

Furthermore, AlGaN/GaN heterostructures do not require modulation doping, which is necessary in GaAs-based devices to create the electron gas at the hetero-interface. The discontinuity of the spontaneous polarization, due to the lack of symmetry in wurtzite crystals, induces free carriers at the interface. In addition, the piezoelectric polarization, due to the strain of the AlGaN layer, plays an important role in increasing the density of carriers in the device channel. In general, semiconductor materials with such polarization properties are referred as polar materials. High-power operation has been achieved by GaN based HEMTs in the millimeter wave frequency range.

In FIG. 1 is depicted a cross-sectional view of a known hetero-structure field effect transistor. In this structure, a Channel narrow-bandgap layer 3, e.g. GaAs or GaN, and an n-type Barrier layer 5 with a wide bandgap, e.g. AlGaAs or AlGaN, are formed in this order over a substrate 4, e.g. sapphire or semi-insulating GaAs. A source electrode 6 and a drain electrode 2 are formed above the n-type layer 5 with a metal layer deposition. A gate electrode 1 is formed of metallic or semiconductor materials so as to be located between the source electrode 6 and the drain electrode 2. This field-effect transistor is usually a normally ON type FET in which a drain current flows when a 0V voltage is applied to the gate, due to the high-concentration two dimensional electron gas generated at the hetero-interface between the n-type AlGaAs (or AlGaN) layer 5 and the undoped GaAs (or GaN) layer 3.

In order to improve the high-frequency performance, the gate length L_{G} of the device has to be reduced. The Lg reduction allows the minimization of the parasitic capacitances associated with the device. This condition is essential for the improvement of RF performance. However, the reduction of Lg alone does not lead to maximum RF performance. The so-called “short channel effects” involve a shift of the threshold voltage and a deterioration of the transconductance and of the output conductance.

In order to avoid these effects in HEMT devices, the proper layer design must keep a high aspect ratio Lg/a where a is the distance between the gate electrode and the two-dimensional electron gas. This scaling down rule involves a limit for HEMT structures due to the gate tunnel current and the degradation of the effective gate length related to the depletion in the recessed regions. In order to increase f_{T} and fₘₐₓ it is therefore necessary to find alternative solutions in order to improve the actual technology.

Another important limitation of these structures is the difficulty to make them operate in enhancement mode. In case of non-polar or semi-polar materials, such as GaAs, an enhancement mode device can be obtained removing the n-doping from the barrier layer region underneath the control terminal through the formation of a recessed gate. In FIG. 2 a cross-sectional view of a known enhancement mode hetero-structure field effect transistor employing GaAs and AlGaAs semiconductor materials is depicted. In this structure, delta doping regions 15 and 11 are used to supply carriers to the channel. As it can be seen, the gate has been recessed in the barrier layer 12 in order to remove the modulation doping of the channel under the control terminal 8, and raise the threshold voltage at positive values. A similar result could be obtained also using two highly doped regions instead of the delta doping profiles.

The enhancement behavior of the previous structure has several disadvantages. In order to isolate the source and the drain terminals from the gate, the gate region must be done smaller than the etched region formed in the barrier layer, leaving two isolating regions 9 and 7 at the sides of the gate. This causes a discontinuity in the doping modulation of the channel, adding two extra resistive paths in the channel. Furthermore, since the carriers in the channel have to travel through the source-gate access region before reaching the controlled region underneath the gate, and similarly through the gate-drain access region before leaving the device, the illustrated structure suffers from high series resistance. Nevertheless, due to trapping and de-trapping phenomena that can take place in the access regions, the device performance can be affected by dispersion phenomena, which represent one of the most important reliability issues in HEMT devices.

HEMT employing polar materials such as GaN and III-Nitride alloys oriented along the [0001] direction, present similar limitations. In these devices, the channel carrier density is a consequence of the polarization discontinuity between the AlGaN (or AlN) barrier and the GaN buffer layer, and cannot be removed by simply recessing the gate. An interesting solution for this problem is illustrated in FIG. 3 and was proposed by Ueno et al. (U.S. Pat. No. 7,528,423). More in particular, as a potential structure for realizing the normally-off type FET, a HFET structure was proposed in which a p-type GaN layer 17, formed on the top of a barrier layer of un-doped AlGaN 21, was used as a gate for the device. The proposed device included also a channel layer of un-doped GaN 19 under the AlGaN barrier 21, where the electron channel is formed.

In this structure, the piezoelectric polarization, generated at the hetero-interface between the GaN channel layer 19 and the AlGaN barrier layer 21, is offset by the piezoelectric polarization generated at the hetero-interface between the AlGaN barrier layer and the GaN control layer 17. As a result, the concentration of two-dimensional electron gas (2DEG) below the GaN control layer is selectively reduced, thereby achieving the normally-off characteristic.

The solution proposed by Ueno et al., even if very efficient in order to obtain an enhancement mode GaN device, still does not solve the problem associated with the extra resistance of the access regions of the device and the dispersion phenomena related to the trapping and de-trapping phenomena of these regions. Furthermore, the electron enhancement in the channel portion under the gate is limited by the parasitic gate diode, which turns on at moderate low positive gate voltages (even if an injection of low mobility holes in the channel allows an increase of the electron population).

There is therefore a need for a new device structure which has a reduced series resistance (and therefore a lower specific on-resistance), and an improved control on the carrier transport so as to effectively reduce the dispersion effects, associated with the charge trapping and de-trapping, that take place in the access regions of the device. Furthermore, the new transistor should have a low parasitic gate capacitance and should be suitable to obtain both enhancement and depletion mode devices.

Although the cited prior art references describe structures that offer some of the described advantages, no one device includes all of them, limiting their ability to solve the problem of obtaining transistors with high RF performance, and low on-resistance per given semiconductor area in integrated circuits.

It is therefore a purpose of the present invention to describe a novel structure of a semiconductor transistor that offers the advantage of improved performances in terms of on-resistance and frequency response combined with a drastically reduction of the dispersion phenomena associated with state-of-the-art HEMT devices.

### SUMMARY OF THE INVENTION

The present invention describes a transistor based on a Hetero junction FET structure, where the access regions have been removed so as to effectively obtain a lower specific on-resistance, and a higher control on the transport properties of the device, drastically reducing the dispersion phenomena associated with these regions. The present invention can be realized both with polar and non-polar (or semi-polar) materials, without requiring delta doping implantation for the enhancement mode configuration. It can be fabricated as enhancement or depletion mode device with higher control on the device threshold voltage, and with superior RF performance. Furthermore, since the absence of access regions, enhancement mode devices can be realized without discontinuity in the channel conductivity, which translate in an even lower on-resistance.

In order to better understand the main concept of the present invention, let us consider the HFET structure illustrated in FIG. 4, which represents the preferred embodiment of the invention. As it can be seen, conventional device regions (source, gate and drain) are present. However, differently from a standard HEMT device, the source 28 and drain 25 regions have been formed directly into the channel layer 27, for example by means of Silicon or Germanium implantations (or an etch step followed by deposition of metal or heavily doped semiconductor materials), after removing selectively the barrier layer. Furthermore, the source and drain regions have been self-aligned with the gate layer 23, removing completely the access regions.

This configuration offers several advantages over a standard HEMT device. First of all, the novel device does not have access regions: the carriers travel directly from/to the source/drain terminal to/from the modulated channel-region under the gate. This characteristic leads to another important consequence, i.e. there is no need to form delta implants (at least in an enhanced mode device), or a recessed gate, since the only barrier region left is the one underneath the gate region. Furthermore, the dispersion phenomena are practically eliminated, since trapping and de-trapping phenomena are usually associated to the access regions of the device.

As shown in FIG. 5, since the peculiar structure of the device, the barrier layer 30 can be also self-aligned with the gate layer 29, so as to reduce the number of process masks required in the device fabrication process. The gate region 29 can be fabricated in highly doped semiconductor or with a Schottky contact (i.e. in metal), depending on the desired device characteristics.

The novel device can be manufactured using both polar or/and non-polar or semi-polar semiconductor materials. An implementation example of the described embodiment is illustrated in FIG. 6, where an AlGaAs barrier 36 and a GaAs channel layer 39 have been used. If the AlGaAs layer is left un-doped or is doped with p-type impurities, the device will behave as an enhancement mode HFET. In order to obtain a depletion mode device, the AlGaAs region must be n-doped, or δ-implants must be introduced into the barrier layer.

As in conventional HEMT devices, if the device is fabricated with polar materials, the depletion mode behavior can be obtained exploiting the polarization discontinuities at the hetero-interfaces. No δ-doping implants are required. However, if desired, the barrier layer can be doped in order to tune the threshold voltage of the device.

When polar materials are utilized, an enhancement mode device can be easily obtained by using a p-doped gate fabricated with the same material of the channel layer, as depicted in FIG. 7. In this structure, the piezoelectric polarization generated at the hetero-interface between the Channel layer 45 and the barrier layer 42 is offset by piezoelectric polarization generated at the hetero-interface between the barrier layer 42 and the control layer 41. As a result, the concentration of two-dimensional electron gas (2DEG) below the GaN control layer is selectively reduced, thereby achieving the normally-off characteristic.

As depicted in FIG. 8, the barrier layer can be replaced with a stack of different layers of different materials in order to improve the device performance. For instance, an AlGaN/AlN stack can be used instead of the barrier layer 42 depicted in FIG. 7, in order to increase the gate barrier and decrease the gate leakage current. Similarly, more than two barrier layers can be used if desired. In the configuration of FIG. 8 the two barrier layers can be doped with different impurities types or concentrations in order to improve the device performance or tune the threshold voltage of the device. Another possibility is to use different molar fraction for the two barrier layers.

In order to increase the voltage swing of the control terminal without turning on the parasitic diode associated with the gate terminal, one of the two barrier layers can be replaced with an insulating layer as depicted in FIG. 9. In this structure, the gate leakage is significantly reduced also for low gate biases. When polar materials are used in this configuration, an extra p-type layer (e.g. p-GaN) can be added between the insulating layer 55 and the barrier layer 60 in order to obtain an enhancement mode device. An example of implementation of this concept is depicted in FIG. 10. In this case, given the piezoelectric polarization of the materials utilized, the self-alignment between the gate and the source/drain regions is optional.

If the device is used as n-channel FET, the channel layer can be p-doped, or left un-doped in order to minimize the impurity scattering phenomena. In the second scenario however, short channel effects, such as Drain induce barrier lowering and Punch-through phenomena, can take place. In order to minimize these undesired effects, a buried barrier layer (e.g. AlGaAs, AlAs, AlGaN or MN) can be added to the structure, so as to improve the confinement of the carriers into the channel. This approach is illustrated in FIG. 11, where an extra barrier 73 has been added under the channel 71.

Another interesting embodiment of the present invention is shown in FIG. 12, where the source and drain regions 82 and 79 are formed directly into the barrier layer 83. Also in this case, as in the previous embodiments, source and drain regions can be fabricated with n+ semiconductor or metallic materials. These regions can be obtained through an implantation process step or by etching the barrier layer 83 and sub-sequentially depositing doped semiconductor or metal in the grooves created. In this second case, the source and drain regions can be realized also with the same material of the channel region in order to decrease the contact resistivity.

In this structure the barrier layer 83 has been doped with p-type impurities in order to electrically isolate the source from the drain region. Furthermore, an extra barrier layer 78 has been added to the structure in order to isolate the source and the drain regions from the gate terminal. The channel layer is un-doped in order to maintain high mobility into the device channel. This configuration is very useful to reduce punch-through phenomena that can arise from the formation of the contacts directly into the channel layer. In this structure the barrier layer 78 may be self-aligned with the gate region.

The contact regions 82 and 79 can be extended down to the channel layer 81 as illustrated in FIG. 12, or they may be realized as depicted in FIG. 13. Another possibility is to make the source and drain regions penetrate the channel layer as shown in FIG. 14. Each of these configurations has advantages and disadvantages, depending on the utilized process technology. The choice of one configuration respect to the other depends on the materials used and the desired characteristics of the resulting device.

FIG. 15 shows an implementation example of the embodiment depicted in FIG. 12. In this case, since polar materials such as GaN and AlGaN oriented along the [0001] direction have been used to fabricate the device, the gate region 98 has been realized with a p-doped GaN layer in order to remove selectively the polarization charge under the gate and obtain a normally-off device. The source and drain regions 103 and 100 can be formed with n+ AlGaN, n+ GaN, or metal depending on the technology available.

FIG. 16 depicts a further embodiment of the present invention, where two lightly doped n− regions 113 and 107 have been added in the barrier layer 111 in order to minimize the electric field in the device. A similar approach is reported in FIG. 17 where only one n-doped diffused region 116 has been added to the HEMT device. In this last structure the lightly doped region operates as drift-region for the HFET device. A similar configuration can be used also in the case where the n+ S/D regions are formed directly into the channel layer as in the case of the preferred embodiment shown in FIG. 4.

If necessary, the gate region and the extra barrier layer can be recessed into the first barrier layer as shown in FIG. 18 in order to increase the control of the gate on the channel population. Furthermore, the extra barrier can be replaced with an insulation layer as depicted in FIG. 19 in order to increase the variation range of the control voltage and, at the same time, decrease the gate leakage of the device. In this case, the gate voltage can be increased without turning on the parasitic diode associated with the gate terminal in conventional HEMT device.

As shown in FIG. 20, when polar materials are used, an extra layer can be added between the insulation layer and the barrier layer in order to remove selectively the polarization charge in the channel layer. In this case the self-alignment of the source and drain regions with the gate is optional.

In FIG. 21 is depicted a further embodiment of the present invention, where the extra barrier layer has been removed. In this configuration, the control terminal 144 must be fabricated with highly p-doped semiconductor, or with an n-schottky contact in order not to short circuit the gate with the source/drain regions. Also in this case, the drain and source regions 150 and 147 can extend partially into the barrier layer 145, or down into the channel layer 149. Two slightly n-doped regions 151 and 146 have been added to the structure between the gate and the source/drain regions in order to reduce the gate leakage and the electric field in the device.

FIG. 22 depicts an implementation example of the previous embodiment. In this structure the gate region 152 is a p-doped GaN layer formed on the top of an AlGaN layer 153. As it can be seen, in this case, since polar materials are used, the self-alignment of the source and drain regions with the gate is optional. Similar consideration can be done for the n-doped regions described in FIG. 21, which can be omitted.

In all the embodiment discussed above a buried layer can be added in order to decrease the short channel effects and increase the control on the carrier transport. Furthermore, a multi-gate configuration can be obtained as shown in FIG. 23. In this structure an extra gate 163 has been added under the buried barrier layer in order to improve the device performance. In particular, in the depicted embodiment the extra gate is a highly doped semiconductor layer.

The two gates can be coupled together or biased differently, one from the other, depending on the application. Many other multi-gate configurations can be obtained starting from the basic concept illustrated in FIG. 23. If the channel region 167 is formed thin enough, the two channels at the upper and lower interface can also merge in a single electron (or hole)—channel, further increasing the control on the carrier transport. The R_{DSon} of the device is much lower due to the enhanced current drive derived from the double channel configuration. Furthermore, if necessary, one or both gate layers 158 and 163 can be divided in more layers of different materials in order to improve the device performance.

As known to anyone skilled in the art, many doping profiles and layers can be added to the structures described above in order to improve the device design and the channel density. Other techniques include the use of δ doping implants to obtain depletion mode devices, and many other variants. Similar considerations hold for the enhancement mode version.

For all the FET structures discussed above, the p-channel version can be obtained. Furthermore, the hetero junction based structures can be realized with standard HFET fabrication process. In particular, the n+ S/D regions can be obtained through doping implantations or by removing partially the channel/barrier layer through a selective etch and depositing directly doped semiconductor materials or metals into the created grooves.

As mentioned above, the materials used in the fabrication process of the previous structures can comprise any type of semiconductor material, including II-VI compound semiconductors, III-V polar (such as GaN, AlN, InN etc. and their alloys) and non polar (such as GaAs, AlAs, InAs etc. and their alloys or non-polar or semi-polar GaN, AlN, InN etc. and their alloys) materials, and/or in some case silicon, germanium, SiGe, sapphire, SiC, etc.

It is therefore an object of the present invention to increase the device performance by decreasing its on-resistance and the control on the device transport, reducing at the same time the dispersion phenomena associated with state-of-the-art HEMT devices.

As is clear to those skilled in the art, this basic system can be implemented in many specific ways, and the above descriptions are not meant to designate a specific implementation.

### BRIEF DESCRIPTIONS OF THE DRAWINGS

The features, objects, and advantages of the present invention will become apparent upon consideration of the following detailed description of the invention when read in conjunction with the drawings in which:

FIG. 1 shows a cross section view of a conventional HFET device (prior art).

FIG. 2 shows a cross section view of a HFET device in GaAs technology (prior art).

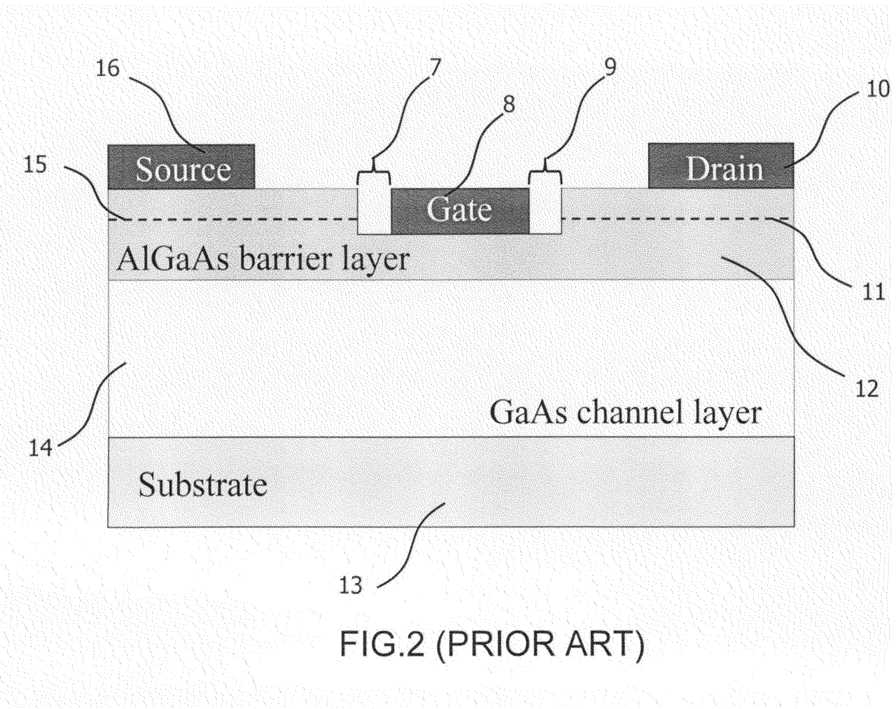

FIG. 3 shows a cross section view of a HFET device in GaN technology (prior art).

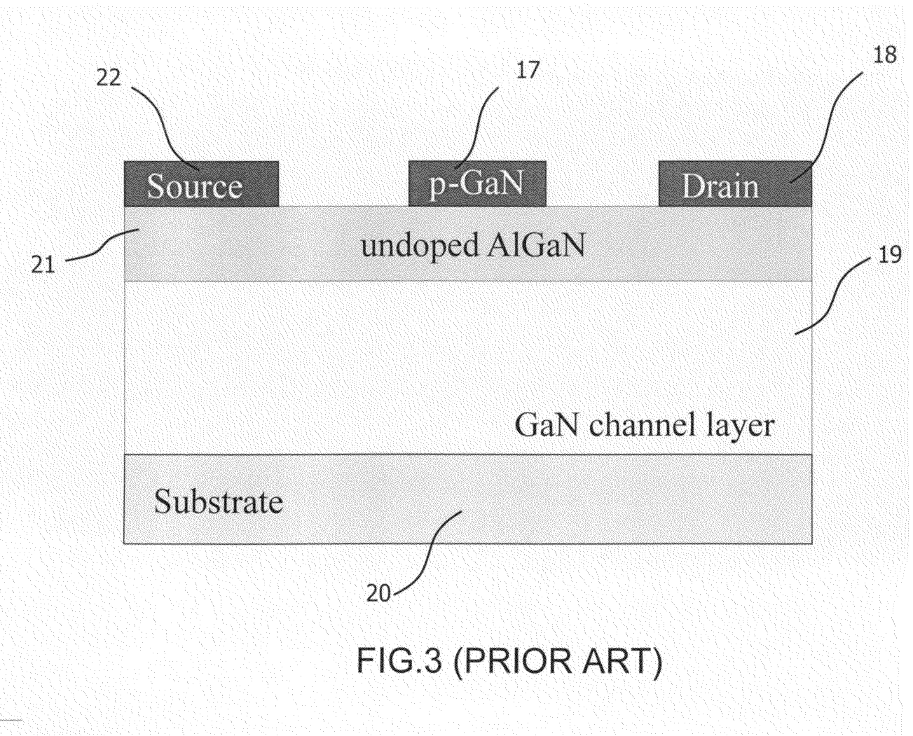

FIG. 4 shows a cross section view of a HFET device according to the preferred embodiment of the invention.

FIG. 5 shows a cross section view of a HFET device according to a further embodiment of the invention, where the barrier layer and the gate region have been self-aligned.

FIG. 6 shows an implementation example of the embodiment of FIG. 5, realized in GaAs technology.

FIG. 7 shows an implementation example of the embodiment of FIG. 5, realized in GaN technology.

FIG. 8 shows a cross section view of an Hetero-structure device according to a further embodiment of the invention, where the barrier layer has been replaced with a stack of two material layers.

FIG. 9 shows a cross section view of a Hetero-structure device according to a further embodiment of the invention, where an insulating layer has been added between the gate region and the barrier layer.

FIG. 10 shows a cross section view of an example of implementation of the embodiment of FIG. 9, realized in polar GaN technology.

FIG. 11 shows a cross section view of an Hetero-structure device according to a further embodiment of the invention, where a buried barrier layer has been added under the channel region in order to improve the carrier confinement into the channel.

FIG. 12 shows a cross section view of an Hetero-structure device according to a further embodiment of the invention, where the source and drain regions have been created in the barrier layer.

FIG. 13 shows a cross section view of an Hetero-structure device according to a further embodiment of the invention, where the source and drain regions does not extend down into the channel layer.

FIG. 14 shows a cross section view of an Hetero-structure device according to a further embodiment of the invention, where the source and drain regions are confined into the barrier layer.

FIG. 15 shows a cross section view of an example of implementation of the embodiment of FIG. 12, realized in polar GaN technology.

FIG. 16 shows a cross section view of an Hetero-structure device according to a further embodiment of the invention, where two lightly n-doped regions have been added between the S/D regions and the gate.

FIG. 17 shows a cross section view of an Hetero-structure device according to a further embodiment of the invention, where a drift region has been added between the drain region and the gate.

FIG. 18 shows a cross section view of an Hetero-structure device according to a further embodiment of the invention, where the gate and the extra barrier have been realized in a recessed barrier layer.

FIG. 19 shows a cross section view of an Hetero-structure device according to a further embodiment of the invention, where an insulating layer has been added between the barrier layer and the gate region.

FIG. 20 shows a cross section view of an example of implementation of the embodiment of FIG. 19, realized in polar GaN technology.

FIG. 21 shows a cross section view of an Hetero-structure device according to a further embodiment of the invention, where the gate region has been placed directly above the barrier layer and the S/D regions have been fabricated into the barrier layer.

FIG. 22 shows a cross section view of an example of implementation of the embodiment of FIG. 21, realized in polar GaN technology.

FIG. 23 shows a cross section view of a double gate Hetero-structure device according to a further embodiment of the invention.

### DETAILED DESCRIPTION OF SPECIFIC EMBODIMENTS

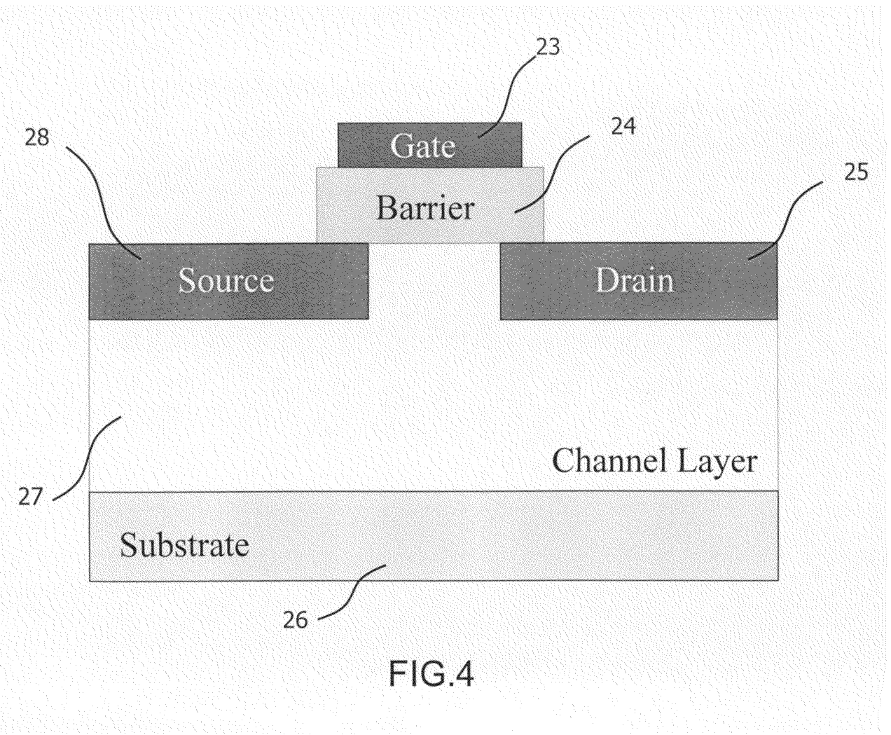

### A FIG. 4

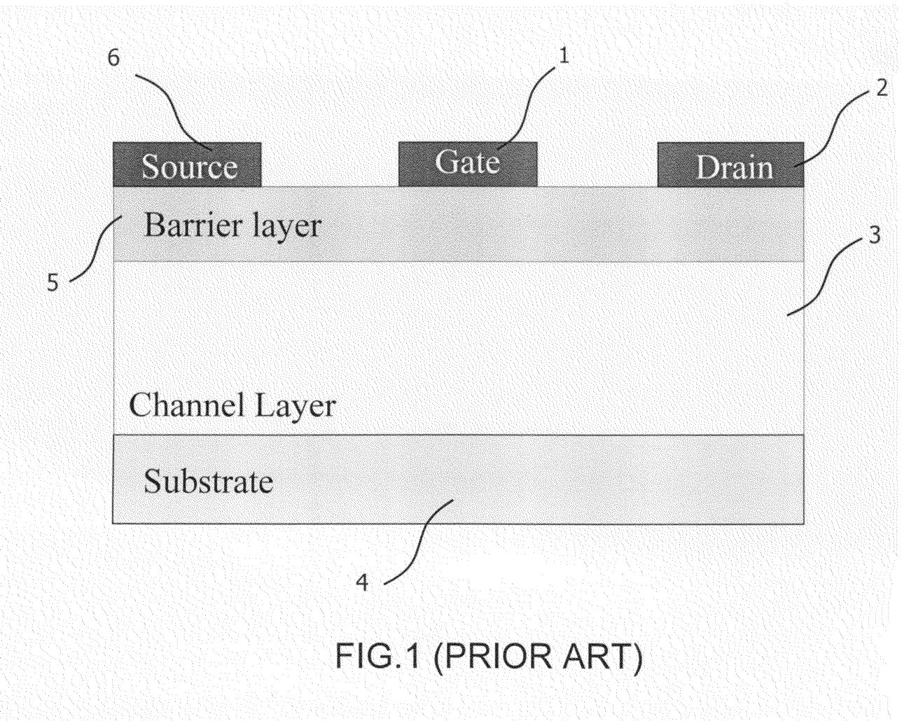

FIG. 4 is showing a Hetero-structure FET (HFET) device according to the preferred embodiment of the invention. The metallic or n+-type semiconductor regions 28 and 25 formed directly into the channel layer 27, define the source and the drain of the transistor. Regions 24 corresponds to the barrier layer of the device, and the channel layer 27 is the region where the electron (or hole)—channel is formed. Region 23, which can be formed using semiconductor materials or metal, corresponds to the gate of the device. As it can be seen, differently from the conventional HEMT structure of FIG. 1, no access regions can be identified in the device.

If the desired device is an n-channel HFET, the channel region should have an electron affinity greater with respect to the barrier layer 24, in order to confine the carrier transport inside the layer 27 during the normal operation of the device. The gate region 23 instead, can be built with the same, greater or lower electron affinity with respect to the barrier layers, depending on the desired device characteristics. If necessary, the gate 23 and/or the barrier layer 24 can be replaced with multi-layer stacks formed by different material layers.

The present invention defines a HFET device where, the access regions have been eliminated so as to effectively obtain a lower specific on-resistance, and a higher control on the transport properties of the device, drastically reducing the dispersion phenomena associated with these regions. The present invention can be realized both with polar and non-polar (or semi-polar) materials, without requiring delta doping implantations (at least for the enhanced mode version). It can be fabricated as an enhancement or depletion device with much more control on the device threshold voltage, and with superior RF performance. Furthermore, since the absence of access regions, enhancement mode devices can be realized without discontinuity in the channel conductivity, which translate in an even lower on-resistance.

Starting from the base concept structure of FIG. 4, an unlimited number of modifications can be adopted depending on the materials used, in order to optimize the device performance. Supply carrier layers and/or barrier layers can be added to the device.

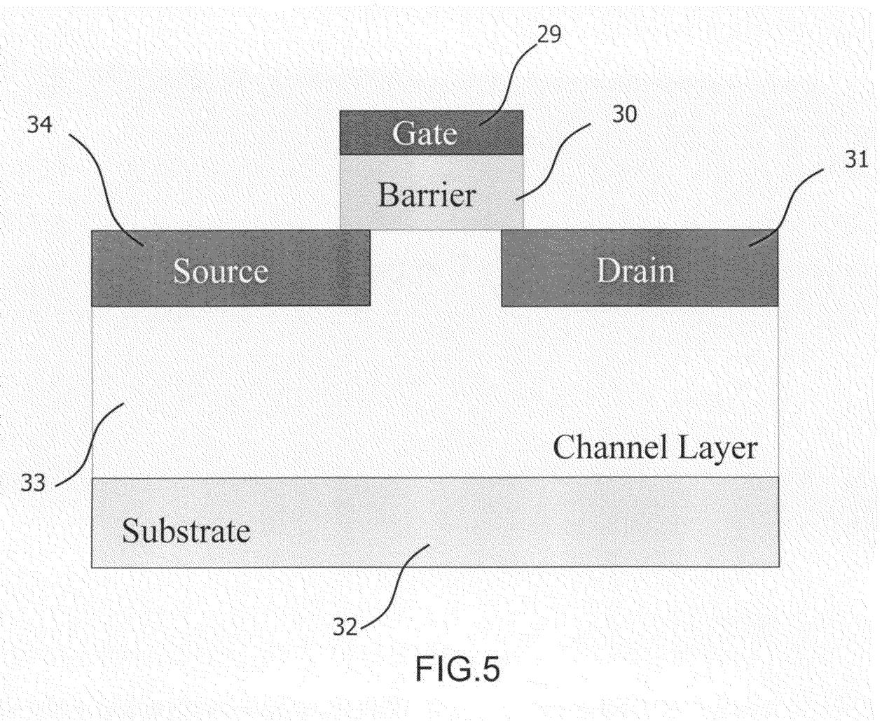

### B FIG. 5

FIG. 5 is depicting a cross-section view of a further embodiment of the invention, where the gate region and the barrier layer have been self-aligned. This configuration allows the reduction of the number of masks required in the fabrication process. Also, in this case, the source region 34 and drain region 31 can be fabricated with highly doped semiconductor material or metal. These regions can be obtained through an implantation process step or by etching the channel layer 33 and sub-sequentially depositing doped semiconductor or metal in the grooves created.

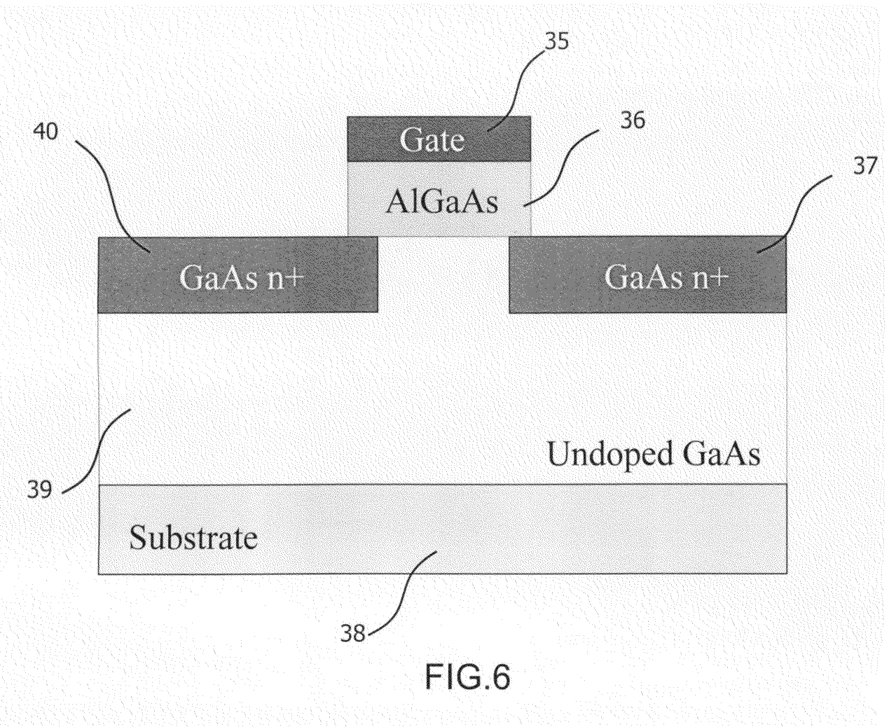

### C FIG. 6

FIG. 6 is depicting a cross-section view of a possible implementation of the embodiment of FIG. 5. In this structure the channel layer 39 has been realized in GaAs whereas, the barrier layer 36 has been realized in AlGaAs. In this configuration, the AlGaAs barrier can be doped or left un-doped, depending on the desired threshold value: if the device operates as a depletion mode, the AlGaAs layer can be doped with n-type impurities (also a δ-doping profile can be used); whereas, in case of enhanced mode device, the barrier layer can be left un-doped or doped with p-type impurities to raise the threshold voltage of the device.

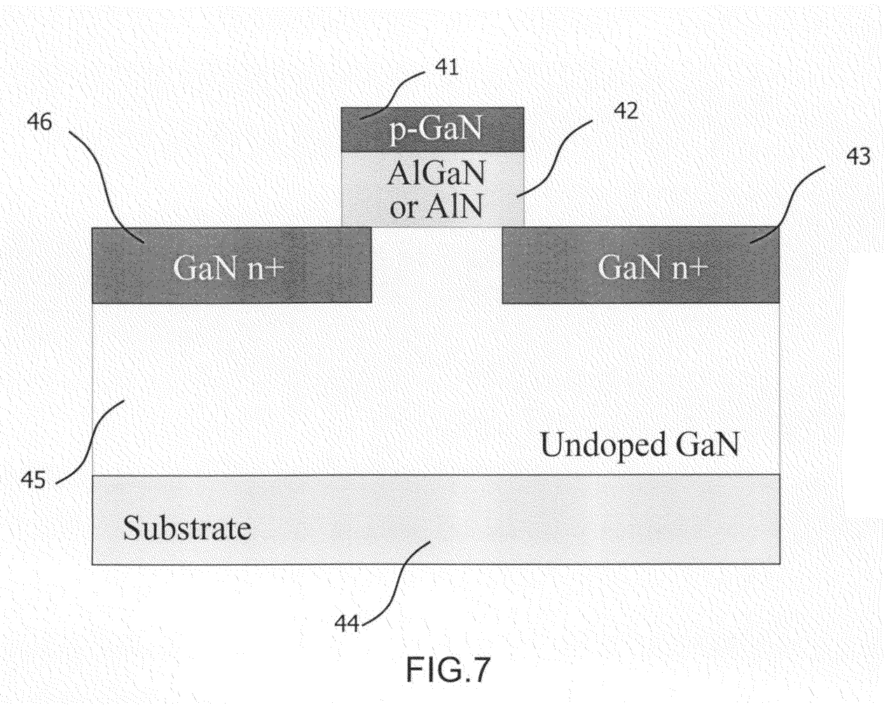

### D FIG. 7

FIG. 7 is depicting another example of implementation of the embodiment of FIG. 5, realized in polar GaN technology. In this structure the gate region 41 has been fabricated in p-doped semiconductor in order to selectively remove the polarization charge under the gate terminal and obtain an enhanced mode device. As well known to anyone skilled in the art, the depletion mode version can be obtained simply substituting the gate region with an n-doped semiconductor layer or a metal plate forming a schottky contact with the AlGaN layer. The GaN channel layer 45 has been left undoped to increase the carrier mobility in the two-dimensional electron gas of the device. The barrier layer 42 can be realized with an AlGaN or AlN layer.

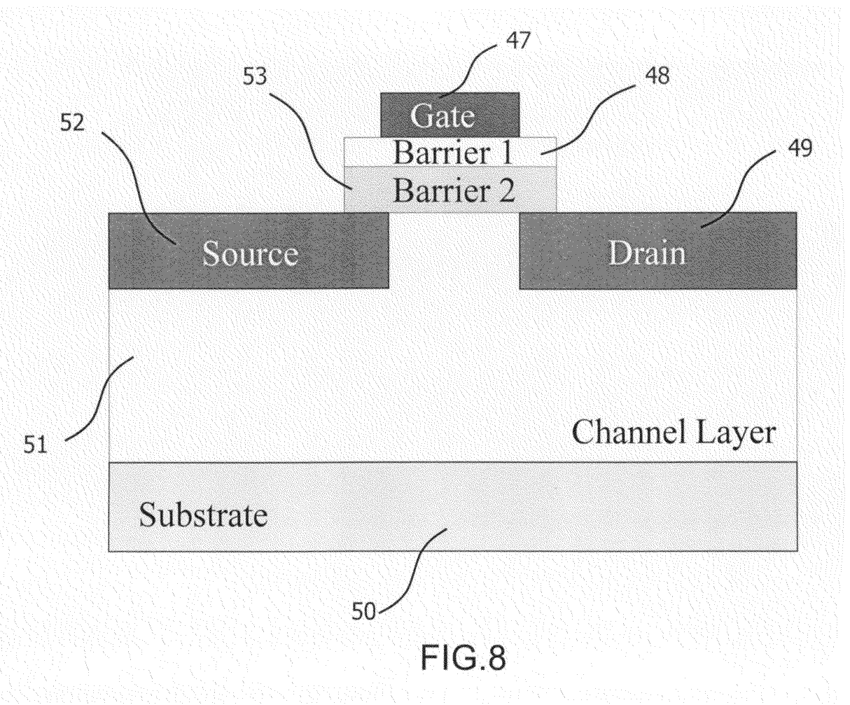

### E FIG. 8

As depicted in FIG. 8, the barrier layer can be replaced with a multi-layer stack employing layers of different materials in order to improve the device performance. For instance, an AlGaN/AlN stack can be used instead of the barrier layer 42 depicted in FIG. 7, in order to raise the gate barrier and lower the gate leakage current during the normal operation of the device.

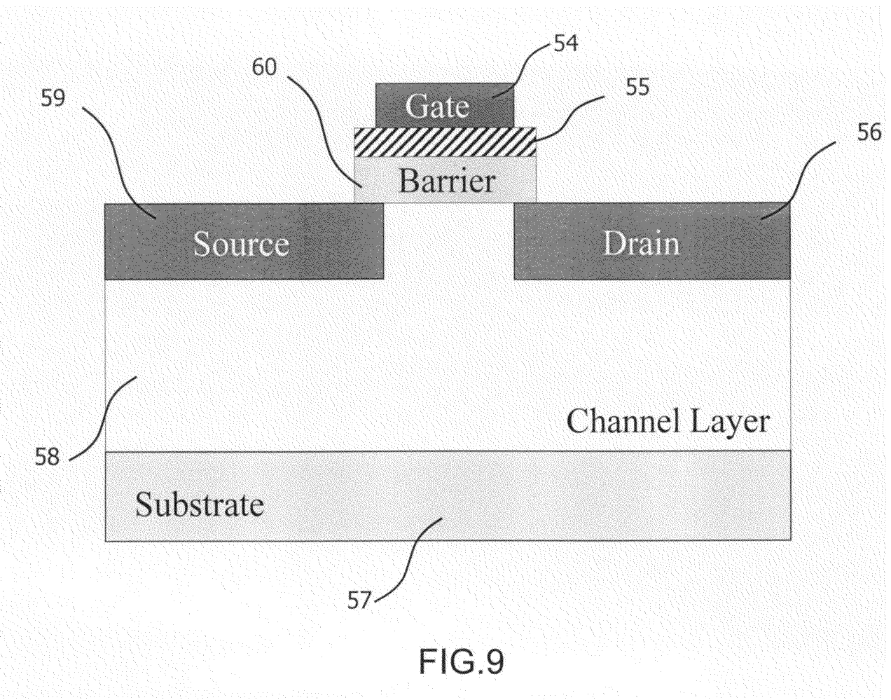

### F FIG. 9

In order to increase the voltage swing of the control terminal without turning on the parasitic diode associated with the gate, an insulating layer can be added between the gate region and the barrier layer as depicted in FIG. 9. In this structure, the gate leakage is significantly reduced also at low gate biases.

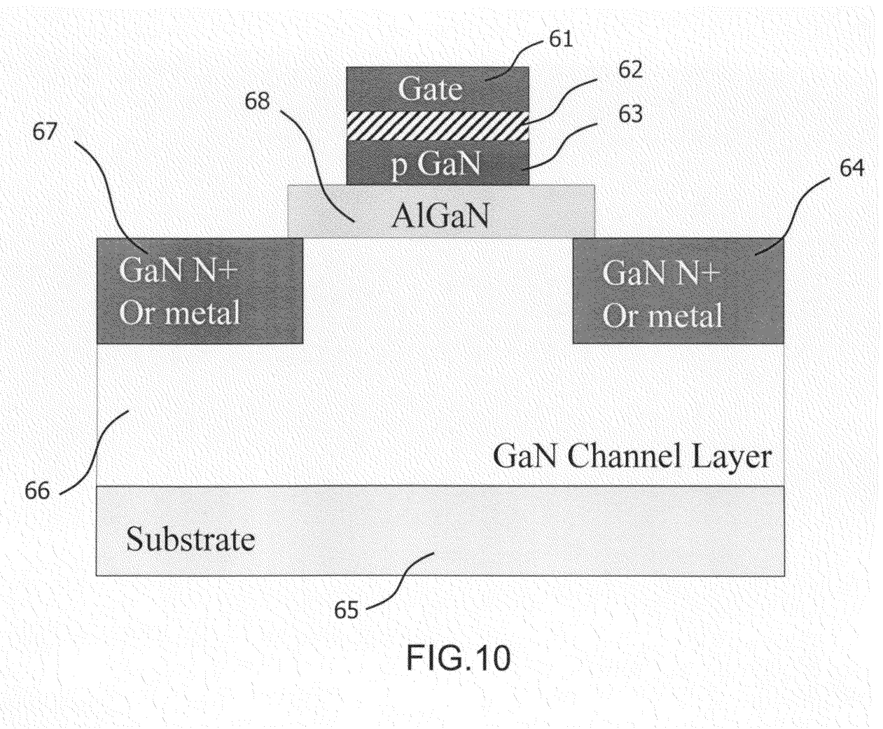

### G FIG. 10

When polar materials are used, an extra p-type layer (e.g. p-GaN) 63 can be added between the insulating layer 62 and the barrier layer 68 in order to obtain an enhancement mode device. An example of implementation of this concept is depicted in FIG. 10. In this case, due to the piezoelectric polarization of the materials used, the self-alignment between the gate and the source/drain regions is optional.

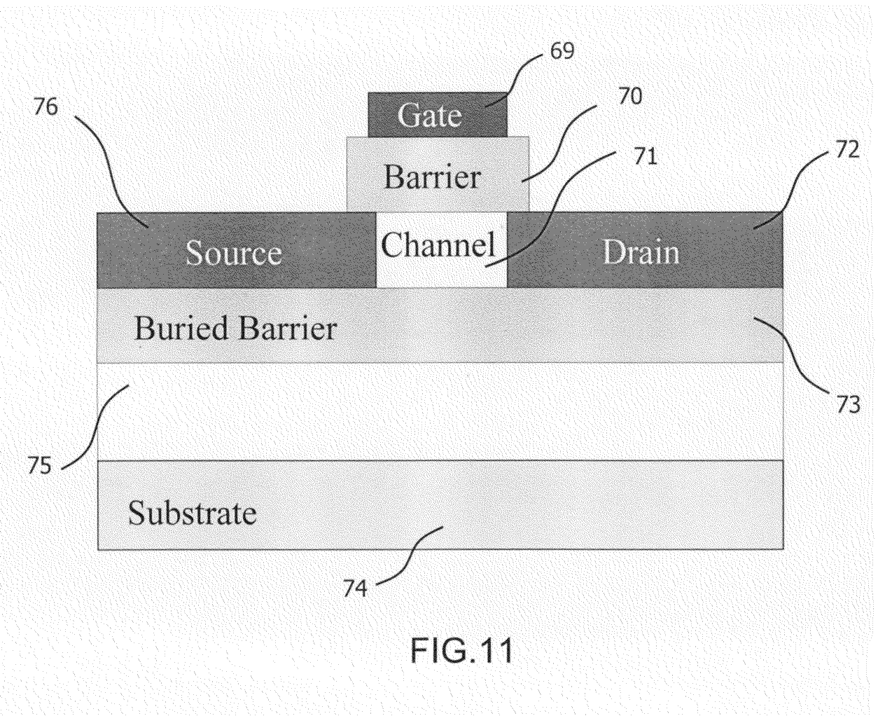

### H FIG. 11

In all the embodiment discussed above, if the device is an n-channel FET, the channel layer can be p-doped, or left un-doped in order to minimize the impurity scattering phenomena. In this last scenario however, short channel effects, such as Drain induced barrier lowering and Punch-through phenomena, can take place. In order to minimize them, a possible solution is to add a buried barrier layer (e.g. AlGaAs, AlAs, AlGaN or AlN) to improve the confinement of the carriers into the channel. This approach is illustrated in FIG. 11, where an extra barrier 73 has been added under the channel 71.

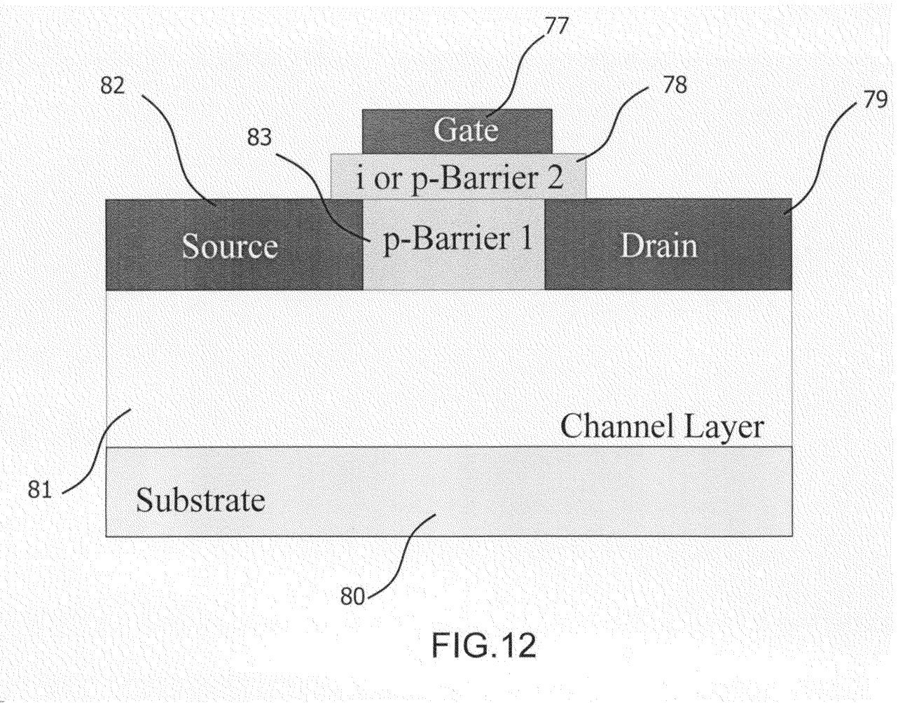

### I FIG. 12

Another interesting embodiment of the present invention is shown in FIG. 12, where the source and drain 82 and 79 are formed directly into the barrier layer 83. Also in this case, as in the previous embodiments, the source and drain regions can be fabricated in highly doped semiconductor material or metal. These regions can be obtained through an implantation process step or by etching the barrier layer 83 and sub-sequentially depositing doped semiconductor or metal in the grooves created. In this second case, the source and drain regions can be realized also with the same material of the channel region in order to decrease the contact resistivity.

In this structure the barrier layer 83 has been doped with p-type impurities in order to create a potential barrier between the source and drain regions, and to prevent a conduction path between them. Furthermore, a second barrier layer 78 has been added above the first one in order to electrically isolate the S/D regions from the gate terminal 77.

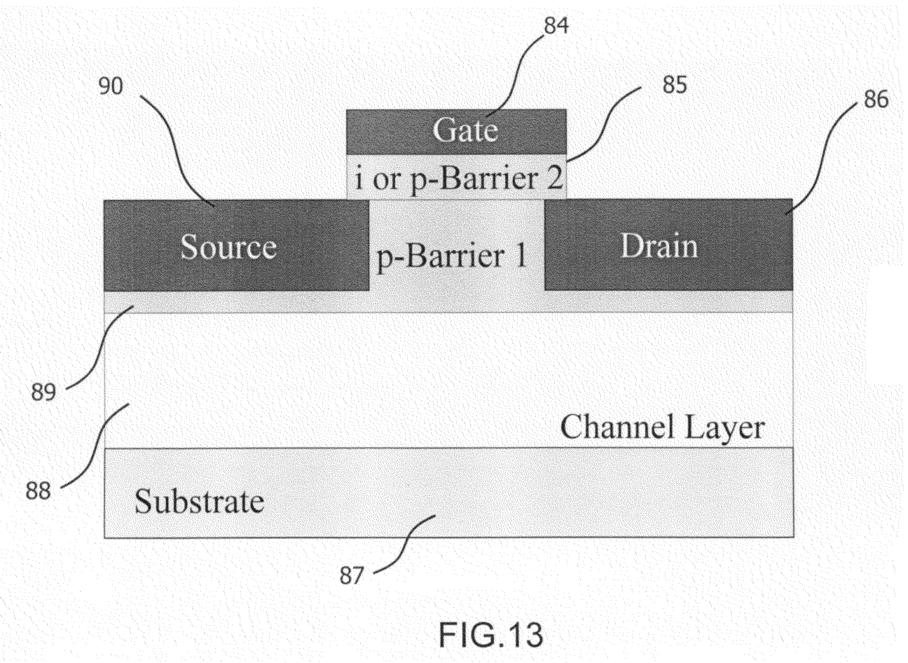

### J FIG. 13

FIG. 13 is depicting a further embodiment of the invention. This structure is similar to the one shown in FIG. 12, with the difference that the source and drain regions 90 and 86 have not been extended down into the channel. This configuration can be useful to avoid short channel effects in the device.

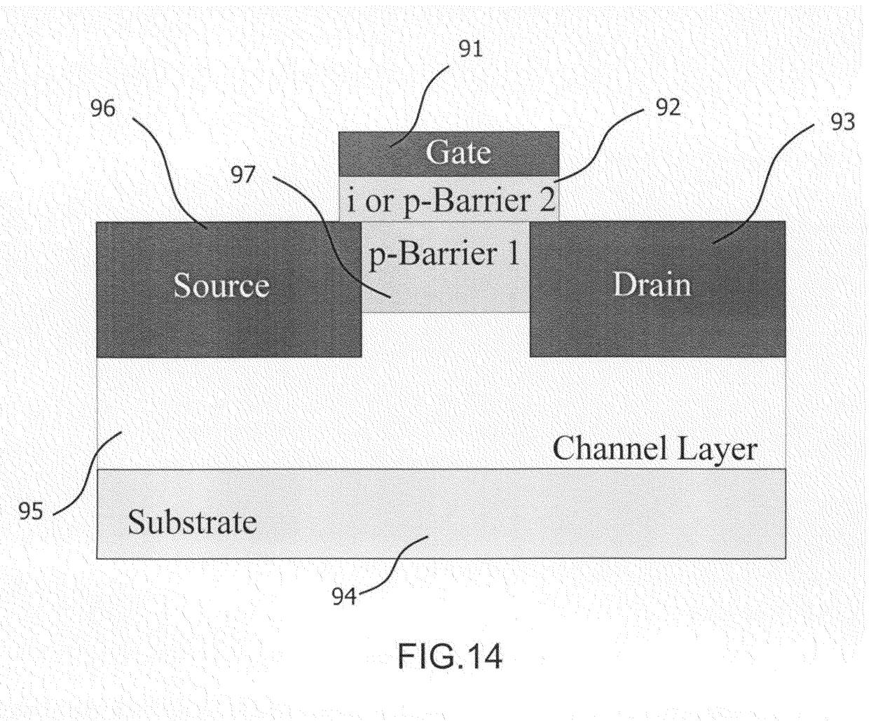

### K FIG. 14

The source and drain regions can extend also down into the channel layer as illustrated in FIG. 14. In this case, these two regions can be realized also with multi-layer stacks of different materials. This configuration offers a lower contact resistance with respect to the previous one, but it can suffer from undesired SCE, which can occur if very short gate lengths are used.

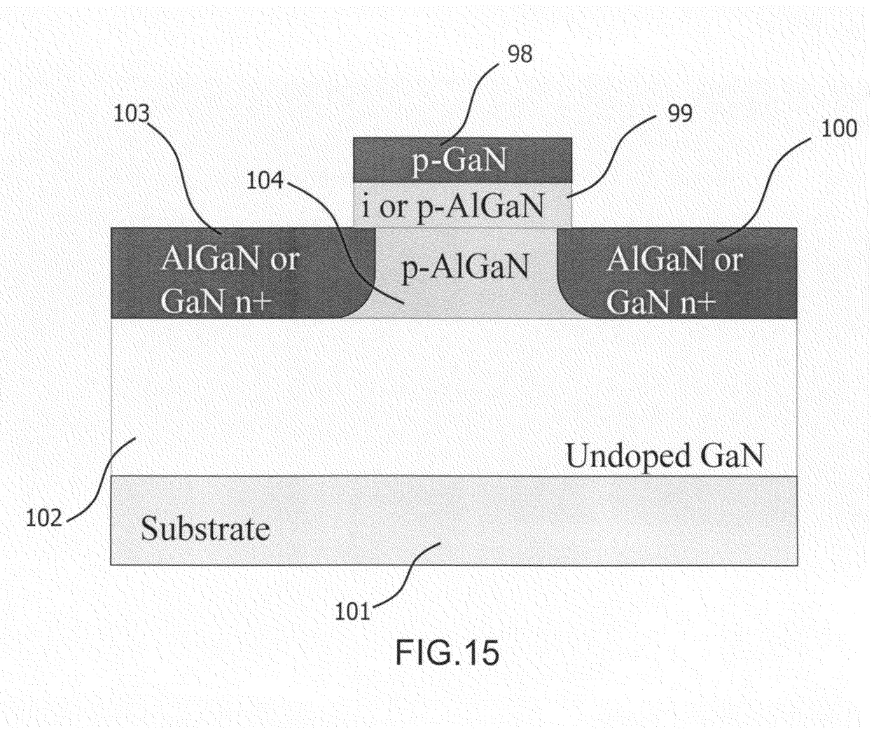

L FIG. 15

FIG. 15 shows an implementation example of the embodiment depicted in FIG. 12. In this case, since polar materials such as GaN and AlGaN grown along the [0001] direction have been used to fabricate the device, the gate region has been formed with a p-doped GaN layer in order to remove selectively the polarization charge under the gate and obtain an enhancement mode device. The source and gate regions can be formed with n+ AlGaN, n+ GaN or metal, depending on the technology available. Furthermore, as well known to anyone skilled in the art, the gate can be realized also with a Schottky contact.

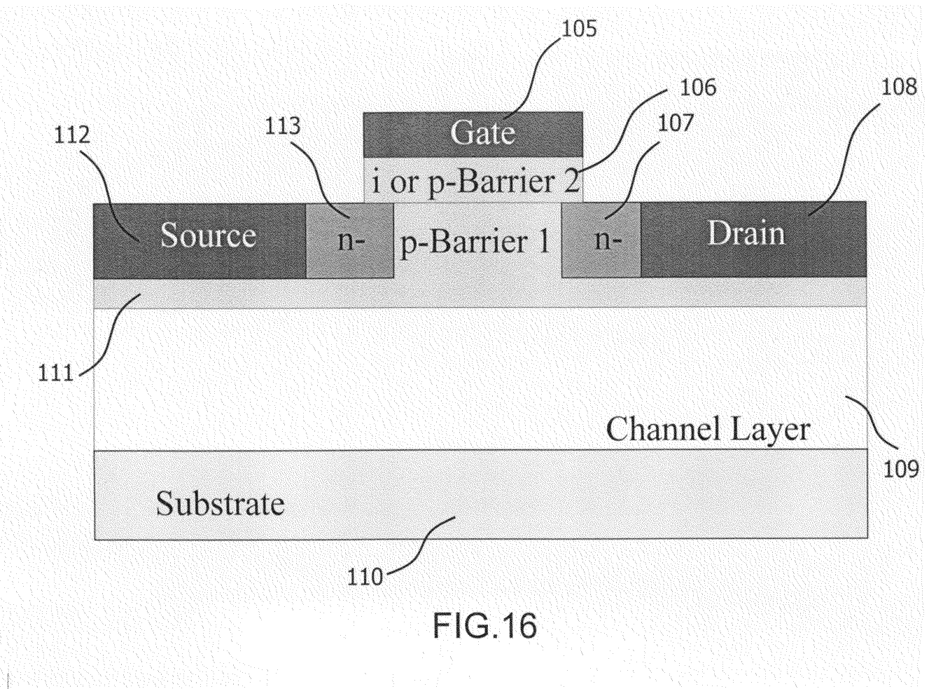

### M FIG. 16

FIG. 16 depicts a further embodiment of the present invention, where two lightly doped regions 113 and 107 have been added in the barrier layer 111 in order to minimize the electric field in the device. These two additional regions smooth the electric field under the control terminal improving the reliability of the HFET structure.

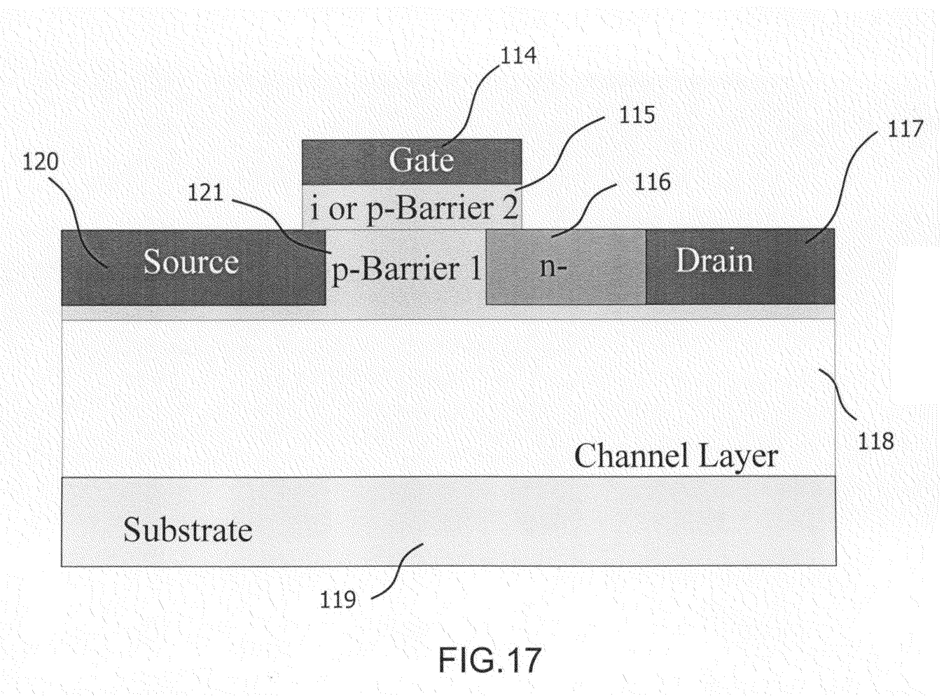

### N FIG. 17

A similar approach is reported in FIG. 17 where only one light diffused region 116 has been added to the HFET device. A similar configuration can be used also in the case where the highly doped S/D regions are formed directly into the channel layer as in the structure described in FIG. 4.

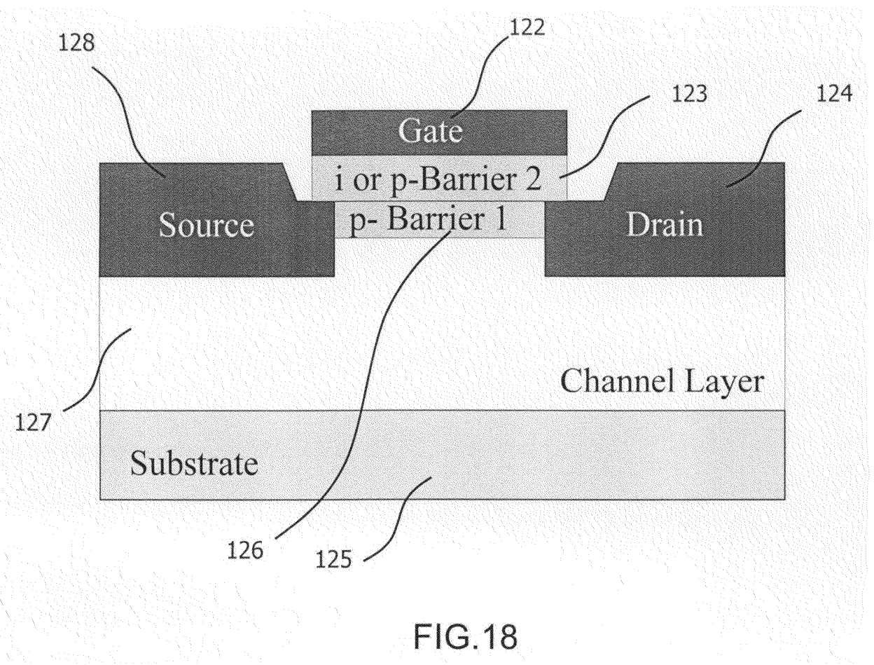

### O FIG. 18

If necessary, the gate region can be recessed into the barrier layer as shown in FIG. 18. This configuration increases the control of the gate terminal on the 2DEG population and raises the threshold voltage of the device allowing an improvement of the device performance. Moreover, since the peculiar geometry of the structure, this design can lead to very low contact resistance, which translates in a further improvement of the FET characteristics.

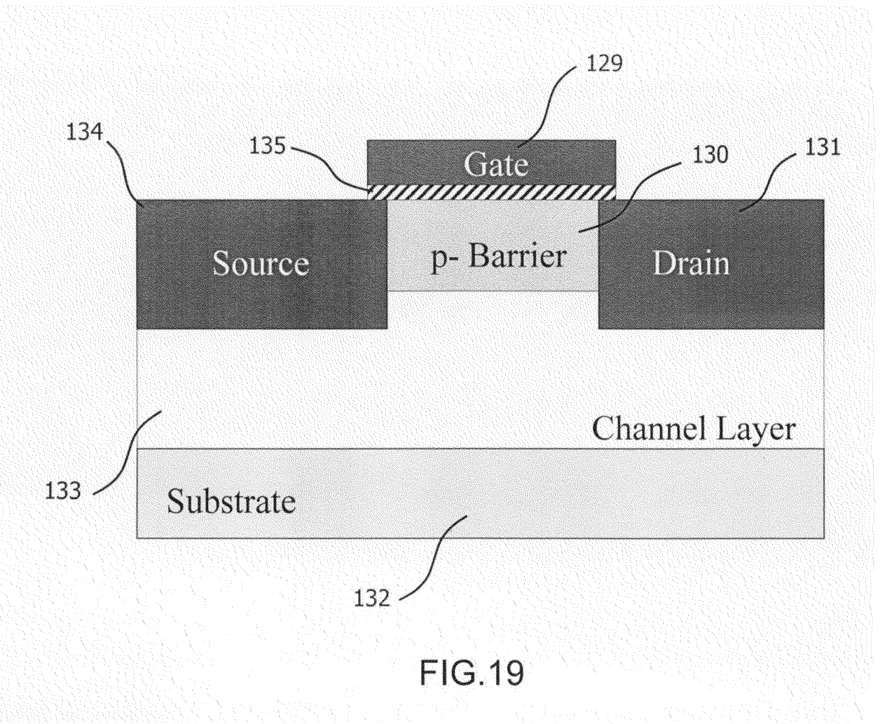

### P FIG. 19

In order to increase the variation range of the control voltage and, at the same time, decrease the gate leakage of the device, the extra barrier layer can be replaced with an insulation layer as depicted in FIG. 19. If properly designed, this configuration offers very high carrier mobility without penalizing the power efficiency of the device.

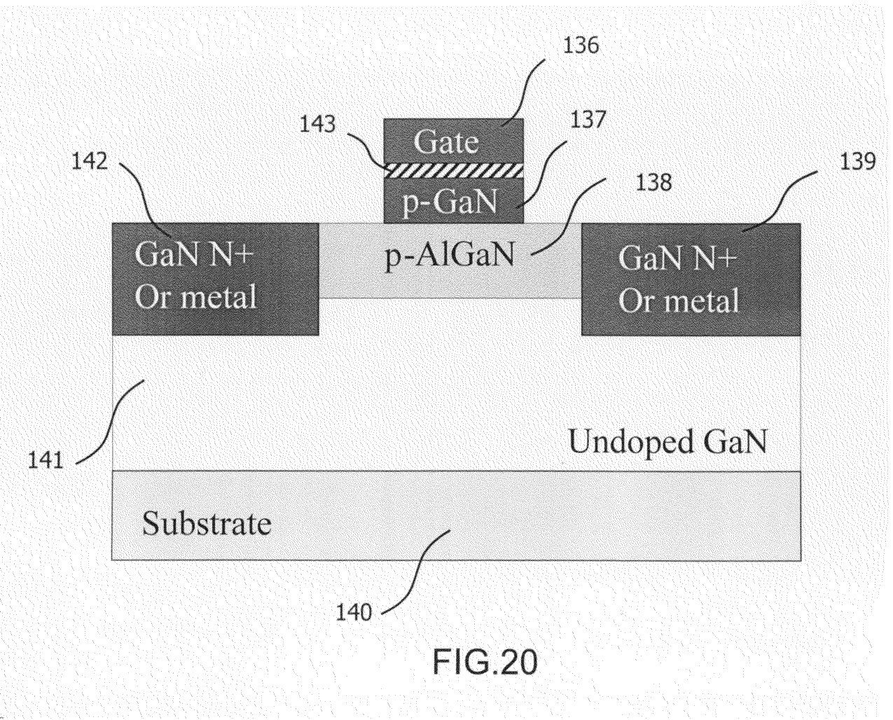

### Q FIG. 20

In case polar materials are used, an extra layer can be added between the insulation layer and the barrier layer in order to cancel the polarization charge in the channel as shown in FIG. 20. In this case the self-alignment of the source and drain regions with the gate is optional.

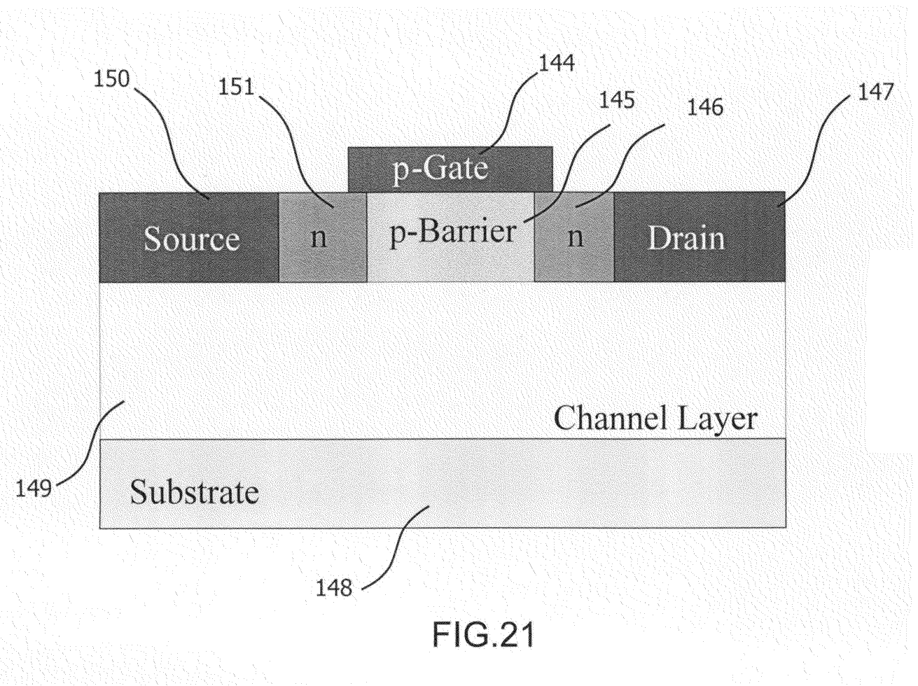

### R FIG. 21

FIG. 21 depicts a further embodiment of the present invention, where the extra barrier layer has been removed. In this configuration, the control terminal 144 must be fabricated with highly p-doped semiconductor, or with an n-schottky contact in order to isolate the gate terminal from the source/drain regions. Also in this case, the drain and source regions 150 and 147 can extend partially into the barrier layer 145, or down into the channel layer 149. Two slightly n-doped regions 151 and 146 have been added to the structure in order to reduce the gate leakage and the electric field in the device.

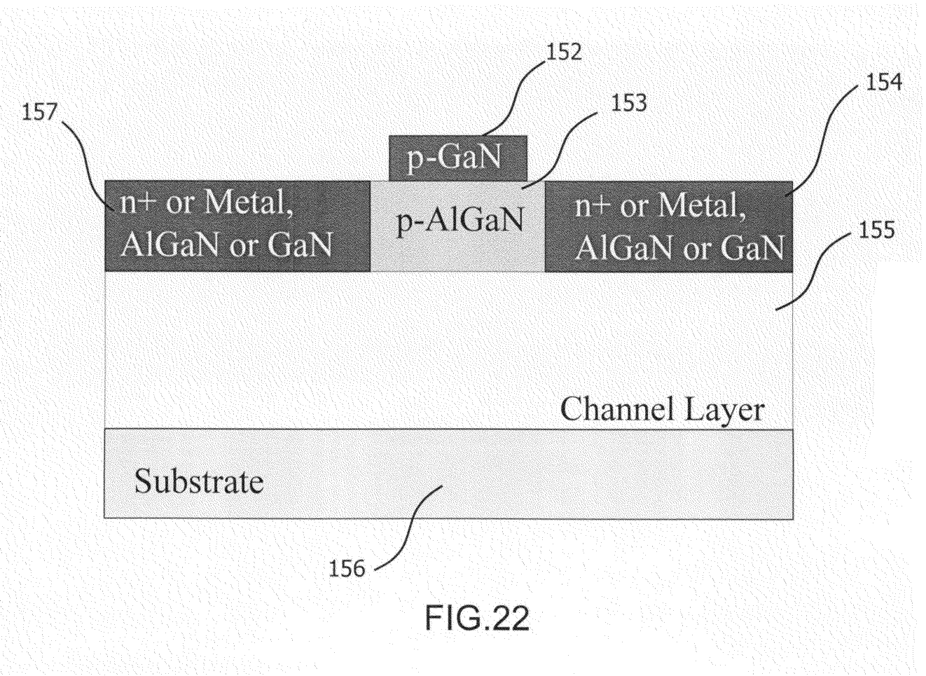

### S FIG. 22

FIG. 22 depicts an implementation example of the embodiment shown in FIG. 21. In this structure the gate region 152 is a p-doped GaN layer deposited on the top of an AlGaN layer 153. As it can be seen, in this case, since polar materials are used, the self-alignment of the source and drain regions with the gate is optional.

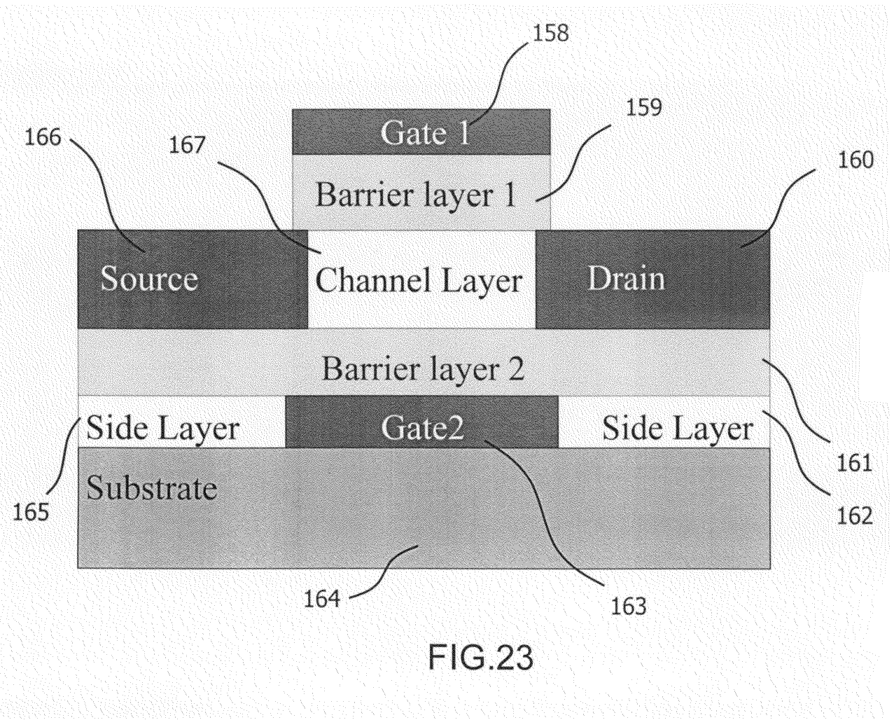

### T FIG. 23

In all the embodiment discussed above a buried layer can be added in order to decrease the short channel effects and increase the control on the carrier transport. Furthermore, a multi-gate configuration can be obtained as shown in FIG. 23. In this structure an extra gate 163 has been added under the buried barrier layer 161 in order to improve the device performance. In particular, in the depicted embodiment, the extra layer is a highly doped semiconductor layer.

The two gates can be coupled together or biased differently one from the other depending on the application. Many other multi-gate configurations can be obtained starting from the basic concept illustrated in FIG. 23. If the channel region 167 is formed thin enough, the two channels at the upper and lower interface can also merge in a single electron (or hole)—channel, further increasing the control on the carrier transport. The R_{DSon} of the device is much lower due to the enhanced current drive derived from the double channel configuration. Furthermore, if necessary, one or both gate layers 158 and 163 can be divided in more layers of different materials in order to improve the device performance.

As known to anyone skilled in the art, many doping profiles and layers can be added to the structures described above in order to improve the device design and the channel density. Other techniques include the use of δ doping implants to obtain depletion mode devices, and many other variants. Similar considerations hold true for the enhancement mode configuration.

For all the FET structures discussed above, the p-channel version can be obtained. Furthermore, the hetero junction based structures can be realized with standard HFET fabrication process. In particular, the highly doped S/D regions can be obtained through doping implantations or by removing partially the channel/barrier layer through a selective etch process step and depositing directly doped material or metal into the formed groves.

As mentioned above, the materials used in the fabrication process of the previous structures can comprise any type of semiconductor material, including II-VI compound semiconductors, III-V polar (such as GaN, AlN, InN etc. and their alloys) and non polar (such as GaAs, AlAs, InAs etc. and their alloys or non-polar or semi-polar GaN, MN, InN etc. and their alloys) materials, and/or in some case Silicon, Germanium, sapphire, SiC, and their alloys, etc.

Although the present invention has been described above with particularity, this was merely to teach one of ordinary skill in the art how to make and use the invention. Many additional modifications will fall within the scope of the invention. Thus, the scope of the invention is defined by the claims which immediately follow.

What is claimed is:

1. A semiconductor hetero-structure field effect transistor comprising:
a semiconductor layer;
at least one semiconductor barrier layer formed above at least a portion of said semiconductor layer;
at least one gate region formed above at least one of said semiconductor barrier layers, and
a source and a drain region formed in said semiconductor layer,
wherein said source and drain regions are formed self-aligned with at least one of said gate regions.

2. The semiconductor hetero-structure field effect transistor of claim 1 wherein said semiconductor layer is a carrier transport layer, and
whereby the conductive channel of said semiconductor hetero-structure field effect transistor is formed in said carrier transport layer when said semiconductor hetero-structure field effect transistor is turned on.

3. The semiconductor hetero-structure field effect transistor of claim 1 further comprising one carrier transport layer;
wherein said semiconductor layer is a second barrier layer;
wherein said second barrier layer is formed above said carrier transport layer;
wherein the conductive channel of said semiconductor hetero-structure field effect transistor is formed in said carrier transport layer when said semiconductor hetero-structure field effect transistor is turned on, and whereby said second barrier layer is made of a semiconductor material with a conductivity type opposite with respect to the conductivity type of said conductive channel.

4. The semiconductor hetero-structure field effect transistor of claim 1 wherein at least one of said semiconductor barrier layers is self-aligned with at least one of said gate regions.

5. The semiconductor hetero-structure field effect transistor of claim 1 wherein at least one of said semiconductor barrier layers is replaced with a barrier layer made of insulating material.

6. The semiconductor hetero-structure field effect transistor of claim 1 further comprising at least one buried barrier layer under the conductive channel of said semiconductor hetero-structure field effect transistor.

7. The semiconductor hetero-structure field effect transistor of claim 1 further comprising multiple gate regions.

8. The semiconductor hetero-structure field effect transistor of claim 1 further comprising at least one lightly doped region self-aligned with at least one of said gate regions,
wherein at least one of said source and drain regions is replaced with a highly conductive region self-aligned with at least one of said lightly doped regions.

9. The semiconductor hetero-structure field effect transistor of claim 1 formed with at least one of the semiconductor materials belonging to the group comprising polar, semi-polar and non-polar III-V compounds semiconductors, polar, semi-polar and non-polar II-VI compounds semiconductors, and semiconductors materials comprising elements of the IV group of the periodic table.

10. The semiconductor hetero-structure field effect transistor of claim 1 wherein at least one of said source and drain regions is replaced with a highly conductive region self-aligned with at least one of said semiconductor barrier layers.

11. A method for manufacturing a semiconductor hetero-structure field effect transistor comprising:
forming at least one semiconductor barrier layer above at least a portion of a semiconductor layer;
forming at least one gate region above at least one of said semiconductor barrier layers;
forming a source and a drain region in said semiconductor layer,
wherein said source and drain regions are formed self-aligned with at least one of said gate regions.

12. The method of claim 11 wherein said semiconductor layer is a carrier transport layer, and
whereby the conductive channel of said semiconductor hetero-structure field effect transistor is formed in said carrier transport layer when said semiconductor hetero-structure field effect transistor is turned on.

13. The method of claim 11 wherein said semiconductor hetero-structure field effect transistor comprises a carrier transport layer;
wherein said semiconductor layer is a second barrier layer;
wherein said second barrier layer is formed above said carrier transport layer;
wherein the conductive channel of said semiconductor hetero-structure field effect transistor is formed in said carrier transport layer when said semiconductor hetero-structure field effect transistor is turned on, and
whereby said second barrier layer is made of a semiconductor material with a conductivity type opposite with respect to the conductivity type of said conductive channel.

14. The method of claim 11 wherein at least one of said semiconductor barrier layers is self-aligned with at least one of said gate regions.

15. The method of claim 11 wherein at least one of said semiconductor barrier layers is replaced with a barrier layer made of insulating material.

16. The method of claim 11 wherein said semiconductor hetero-structure field effect transistor comprises at least one buried barrier layer under the conductive channel of said semiconductor hetero-structure field effect transistor.

17. The method of claim 11 wherein said semiconductor hetero-structure field effect transistor comprises at least one lightly doped region self-aligned with at least one of said gate regions, and
wherein at least one of said source and drain regions is replaced with a highly conductive region self-aligned with at least one of said lightly doped regions.

18. The method of claim 11 wherein at least one of said source and drain regions is replaced with a highly conductive region self-aligned with at least one of said semiconductor barrier layers.

19. A semiconductor hetero-structure field effect transistor comprising:
a carrier transport layer;
at least one semiconductor barrier layer formed above at least a portion of said carrier transport layer;
at least one gate region formed above at least one of said semiconductor barrier layers;
a source and a drain region formed at least partially in at least one of said semiconductor barrier layers;
wherein the conductive channel of said semiconductor hetero-structure field effect transistor is formed in said carrier transport layer when said semiconductor hetero-structure field effect transistor is turned on, and
whereby at least one of said semiconductor barrier layers is made of a semiconductor material with a conductivity type opposite with respect to the conductivity type of said conductive channel.

20. The semiconductor hetero-structure field effect transistor of claim 19 further comprising at least one lightly doped region self-aligned with at least one of said gate regions, and
wherein at least one of said source and drain regions is replaced with a highly conductive region self-aligned with at least one of said lightly doped regions.
